(19) United States
(12) Patent Application Publication
(10) Pub. No.: US 2012/0024695 A1
(43) Pub. Date: Feb. 2, 2012

(54) SYSTEMS AND METHODS FOR HIGH-RATE DEPOSITION OF THIN FILM LAYERS ON PHOTOVOLTAIC MODULE SUBSTRATES

(75) Inventor: Russell Weldon Black, Longmont, CO (US)

(73) Assignee: PRIMESTAR SOLAR, INC., Arvada, CO (US)

(21) Appl. No.: 13/047,189

(22) Filed: Mar. 14, 2011

(51) Int. Cl. C23C 14/34; C23C 14/38; C23C 14/14; C23C 14/35

(52) U.S. Cl. 204/192.29; 204/298.25; 204/298.09; 204/298.13; 204/192.26

(57) ABSTRACT

Apparatus and processes for sequential sputtering deposition of a target source material as a thin film on a photovoltaic module substrate are provided. The apparatus includes a first sputtering deposition chamber and a second sputtering deposition chamber that are integrally connected such that the substrates being transported through the apparatus are kept at a system pressure that is less than about 760 Torr. The load vacuum chamber is connected to a load vacuum pump configured to reduce the pressure within the load vacuum chamber to an initial load pressure. The first sputtering deposition chamber includes a first target, and the second sputtering deposition chamber includes a second target. A conveyor system is operably disposed within the apparatus and configured for transporting substrates in a serial arrangement into and through load vacuum chamber, into and through the first sputtering deposition chamber, and into and through the second sputtering deposition chamber at a controlled speed.

### FIELD OF THE INVENTION

The subject matter disclosed herein relates generally to systems and methods for deposition of thin films on a substrate, and more particularly to a high throughput system for deposition of multiple thin film layers on photovoltaic module substrates.

### BACKGROUND OF THE INVENTION

Thin film photovoltaic (PV) modules (also referred to as “solar panels” or “solar modules”) are gaining wide acceptance and interest in the industry, particularly modules based on cadmium telluride (CdTe) paired with cadmium sulfide (CdS) as the photo-reactive components. CdTe is a semiconductor material having characteristics particularly suited for conversion of solar energy (sunlight) to electricity. For example, CdTe has an energy bandgap of 1.45 eV, which enables it to convert more energy from the solar spectrum as compared to lower bandgap (1.1 eV) semiconductor materials historically used in solar cell applications. Also, CdTe converts energy more efficiently in lower or diffuse light conditions as compared to the lower bandgap materials and, thus, has a longer effective conversion time over the course of a day or in low-light (e.g., cloudy) conditions as compared to other conventional materials.

Typically, CdTe PV modules include multiple film layers deposited on a glass substrate before deposition of the CdTe layer. For example, a transparent conductive oxide (TCO) layer is first deposited onto the surface of the glass substrate, and a resistive transparent buffer (RTB) layer is then applied on the TCO layer. The RTB layer may be a zinc-tin oxide (ZTO) layer and may be referred to as a “ZTO layer.” A cadmium sulfide (CdS) layer is applied on the RTB layer. These various layers may be applied in a conventional sputtering deposition process that involves ejecting material from a target (i.e., the material source), and depositing the ejected material onto the substrate to form the film.

Solar energy systems using CdTe PV modules are generally recognized as the most cost efficient of the commercially available systems in terms of cost per watt of power generated. However, the advantages of CdTe not withstanding, sustainable commercial exploitation and acceptance of solar power as a supplemental or primary source of industrial or residential power depends on the ability to produce efficient PV modules on a large scale and in a cost effective manner. The capital costs associated with production of PV modules, particularly the machinery and time needed for deposition of the multiple thin film layers discussed above, is a primary commercial consideration.

Accordingly, there exists an ongoing need in the industry for an improved system for economically feasible and efficient large scale production of PV modules, particularly CdTe based modules.

### BRIEF DESCRIPTION OF THE INVENTION

Aspects and advantages of the invention will be set forth in part in the following description, or may be obvious from the description, or may be learned through practice of the invention.

An apparatus is generally provided for sequential sputtering deposition of a target source material as a thin film on a photovoltaic module substrate. The apparatus includes a load vacuum chamber, a first sputtering deposition chamber, and a second sputtering deposition chamber. The load vacuum chamber is connected to a load vacuum pump configured to reduce the pressure within the load vacuum chamber to an initial load pressure. The first sputtering deposition chamber includes a first target, which can be configured to deposit a first thin film layer on a substrate. The second sputtering deposition chamber includes a second target, which can be configured to deposit a second thin film layer on a substrate. A conveyor system is operably disposed within the apparatus and configured for transporting substrates in a serial arrangement into and through load vacuum chamber, into and through the first sputtering deposition chamber, and into and through the second sputtering deposition chamber at a controlled speed. The first sputtering deposition chamber and the second sputtering deposition chamber are integrally connected such that the substrates being transported through the apparatus are kept at a system pressure that is less than about 760 Torr.

A process is also generally provided for manufacturing a thin film cadmium telluride thin film photovoltaic device. A substrate is transported into a load vacuum chamber connected to a load vacuum pump, and a vacuum is drawn in the load vacuum chamber using the load vacuum pump until an initial load pressure is reached in the load vacuum chamber. The substrate is then transferred from the load vacuum chamber into a first sputtering deposition chamber including a first target source material, and the first target source material is sputtered to form a first thin film layer on the substrate. The substrate is then transferred from the first sputtering deposition chamber into a second sputtering deposition chamber including a second target source material, and the second target source material is sputtered to form a second thin film layer on the first thin film layer. The substrate is transported through first sputtering deposition chamber and the second sputtering deposition chamber at a system pressure that is less than about 760 Torr.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWING

A full and enabling disclosure of the present invention, including the best mode thereof, directed to one of ordinary skill in the art, is set forth in the specification, which makes reference to the appended figures, in which:

FIG. 1 is a cross-sectional view of a CdTe photovoltaic module;

FIG. 2 shows a top plan view of an exemplary system in accordance with one embodiment of the present invention;

FIG. 3 is a perspective view of an embodiment of a substrate carrier configuration;

FIG. 4 is a perspective view of an alternative embodiment of a substrate carrier configuration;

FIG. 5 is diagrammatic view of an embodiment of a sputtering chamber for deposition of a thin film on a substrate; and,

FIG. 6 is a diagrammatic view of an alternative embodiment of a sputtering chamber.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is described as “on” or “over” another layer or substrate, it is to be understood that the layers can either be directly contacting each other or have another layer or feature between the layers, unless otherwise expressly stated. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

Generally speaking, methods and systems are presently disclosed for increasing the efficiency and/or consistency of in-line manufacturing of cadmium telluride thin film photovoltaic devices. Specifically, a first sputtering deposition chamber and a second sputtering deposition chamber, separated by at least one buffer vacuum chamber, are present in the system 100. The first sputtering deposition chamber, the vacuum buffer chamber(s), and the second sputtering deposition chamber are integrally interconnected such that substrates passing through and between these chambers are not exposed to the outside atmosphere. For example, the first sputtering deposition chamber and the second sputtering deposition chamber can be integrally connected such that the substrates being transported through the apparatus are kept at a system pressure that is less than about 760 Torr (e.g., less than about 250 mTorr, such as about 1 mTorr to about 100 mTorr).

In one particular embodiment, integrated systems and methods for thin film deposition of the resistive transparent buffer (RTB) layer and the cadmium sulfide layer on the substrate are generally disclosed. For example, the integrated systems and methods can be utilized to first deposit the RTB layer on the substrate. For instance, the RTB layer can be sputtered from a RTB target (e.g., including a zinc tin oxide (ZTO) target) onto a conductive transparent oxide layer on the substrate. The substrate can then be transferred from the first sputtering chamber to a vacuum buffer chamber to remove any particles from the substrate and/or chamber atmosphere before depositing subsequent layers (e.g., any excess particles in the first sputtering atmosphere). Then, the cadmium sulfide layer can be deposited on the RTB layer, such as by sputtering a sputtering target including cadmium sulfide.

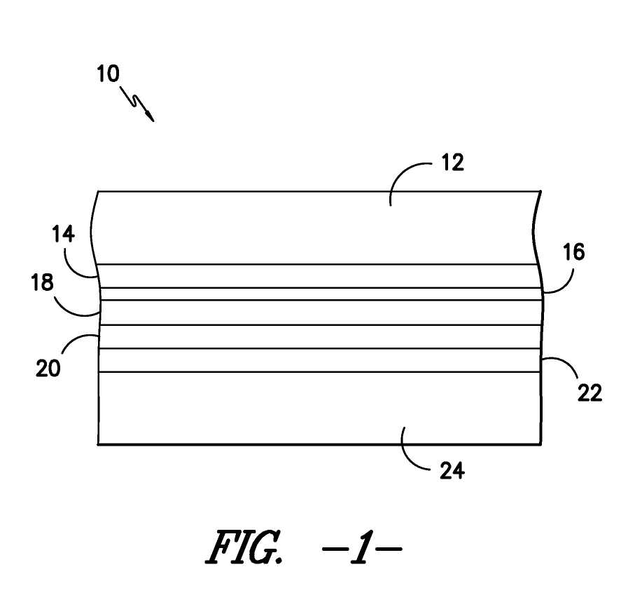

As mentioned, the present system and method have particular usefulness for deposition of multiple thin film layers in the manufacture of PV modules, especially CdTe modules. FIG. 1 represents an exemplary CdTe module 10 that can be made at least in part according to system and method embodiment described herein. The module 10 includes a top sheet of glass as the substrate 12, which may be a high-transmission glass (e.g., high transmission borosilicate glass), low-iron float glass, or other highly transparent glass material. The glass is generally thick enough to provide support for the subsequent film layers (e.g., from about 0.5 mm to about 10 mm thick), and is substantially flat to provide a good surface for forming the subsequent film layers.

A transparent conductive oxide (TCO) layer 14 is shown on the substrate 12 of the module 10 in FIG. 1. The TCO layer 14 allows light to pass through with minimal absorption while also allowing electric current produced by the module 10 to travel sideways to opaque metal conductors (not shown). The TCO layer 14 can have a thickness between about 0.1 μm and about 1 μm, for example from about 0.1 μm to about 0.5 μm, such as from about 0.25 μm to about 0.35 μm.

A resistive transparent buffer (RTB) layer 16 is shown on the TCO layer 14. This RTB layer 16 is generally more resistive than the TCO layer 14 and can help protect the module 10 from chemical interactions between the TCO layer 14 and the additional layers subsequently deposited during processing of the module 10. In certain embodiments, the RTB layer 16 can have a thickness between about 0.075 μm and about 1 μm, for example from about 0.1 μm to about 0.5 μm. In particular embodiments, the RTB layer 16 can have a thickness between about 0.08 μm and about 0.2 μm, for example from about 0.1 μm to about 0.15 μm. In particular embodiments, the RTB layer 16 can include, for instance, a combination of zinc oxide (ZnO) and tin oxide (SnO₂), and is referred to as a zinc-tin oxide (“ZTO”) layer 16.

The CdS layer 18 is shown on ZTO layer 16 of the module 10 of FIG. 1. The CdS layer 18 is a n-type layer that generally includes cadmium sulfide (CdS) but may also include other materials, such as zinc sulfide, cadmium zinc sulfide, etc., and mixtures thereof, as well as dopants and other impurities. The CdS layer 18 may include oxygen up to about 25% by atomic percentage, for example from about 5% to about 20% by atomic percentage. The CdS layer 18 can have a wide band gap (e.g., from about 2.25 eV to about 2.5 eV, such as about 2.4 eV) in order to allow most radiation energy (e.g., solar radiation) to pass. As such, the cadmium sulfide layer 18 is considered a transparent layer on the device 10.

The CdTe layer 20 is shown on the cadmium sulfide layer 18 in the exemplary module 10 of FIG. 1. The CdTe layer 20 is a p-type layer that generally includes cadmium telluride (CdTe), but may also include other materials. As the p-type layer of the module 10, the CdTe layer 20 is the photovoltaic layer that interacts with the CdS layer 18 (i.e., the n-type layer) to produce current from the absorption of radiation energy by absorbing the majority of the radiation energy passing into the module 10 due to its high absorption coefficient and creating electron-hole pairs. The CdTe layer 20 can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the CdTe layer 20) across the junction to the n-type side (i.e., the CdS layer 18) and, conversely, holes may pass from the n-type side to the p-type side. Thus, the p-n junction formed between the CdS layer 18 and the CdTe layer 20 forms a diode in which the charge imbalance leads to the creation of an electric field spanning the p-n junction. Conventional current is allowed to flow in only one direction and separates the light induced electron-hole pairs.

The cadmium telluride layer 20 can be formed by any known process, such as vapor transport deposition, chemical vapor deposition (CVD), spray pyrolysis, electro-deposition, sputtering, close-space sublimation (CSS), etc. In particular embodiments, the CdTe layer 20 can have a thickness between about 0.1 μm and about 10 μm, such as from about 1 μm and about 5 μm.

A series of post-forming treatments can be applied to the exposed surface of the CdTe layer 20. These treatments can tailor the functionality of the CdTe layer 20 and prepare its surface for subsequent adhesion to the back contact layer(s) 22. For example, the cadmium telluride layer 20 can be annealed at elevated temperatures (e.g., from about 350° C. to about 500° C., such as from about 375° C. to about 424° C.) for a sufficient time (e.g., from about 1 to about 10 minutes) to create a quality p-type layer of cadmium telluride. Without wishing to be bound by theory, it is believed that annealing the cadmium telluride layer 20 (and the module 10) converts the normally lightly p-type doped, or even n-type doped CdTe layer 20 to a more strongly p-type layer having a relatively low resistivity. Additionally, the CdTe layer 20 can recrystallize and undergo grain growth during annealing.

Additionally, copper can be added to the CdTe layer 20. Along with a suitable etch, the addition of copper to the CdTe layer 20 can form a surface of copper telluride (Cu₂Te) on the CdTe layer 20 in order to obtain a low-resistance electrical contact between the cadmium telluride layer 20 (i.e., the p-type layer) and a back contact layer(s) 22.

The back contact layer 22 generally serves as the back electrical contact, in relation to the opposite, TCO layer 14 serving as the front electrical contact. The back contact layer 22 can be formed on, and in one embodiment is in direct contact with, the CdTe layer 20. The back contact layer 22 is suitably made from one or more highly conductive materials, such as elemental nickel, chromium, copper, tin, aluminum, gold, silver, technetium or alloys or mixtures thereof. Additionally, the back contact layer 22 can be a single layer or can be a plurality of layers. In one particular embodiment, the back contact layer 22 can include graphite, such as a layer of carbon deposited on the p-layer followed by one or more layers of metal, such as the metals described above. The back contact layer 22, if made or comprised of one or more metals, is suitably applied by a technique such as sputtering or metal evaporation. If it is made from a graphite and polymer blend, or from a carbon paste, the blend or paste is applied to the semiconductor device by any suitable method for spreading the blend or paste, such as screen printing, spraying or by a “doctor” blade. After the application of the graphite blend or carbon paste, the device can be heated to convert the blend or paste into the conductive back contact layer. A carbon layer, if used, can be from about 0.1 μm to about 10 μm in thickness, for example from about 1 μm to about 5 μm. A metal layer of the back contact, if used for or as part of the back contact layer 22, can be from about 0.1 μm to about 1.5 μm in thickness.

In the embodiment of FIG. 1, an encapsulating glass 24 is shown on the back contact layer 22. Other components (not shown) can be included in the exemplary module 10, such as bus bars, external wiring, laser etches, etc. The module 10 may be divided into a plurality of individual cells that, in general, are connected in series in order to achieve a desired voltage, such as through an electrical wiring connection. Each end of the series connected cells can be attached to a suitable conductor, such as a wire or bus bar, to direct the photovoltaically generated current to convenient locations for connection to a device or other system using the generated electric. A convenient means for achieving the series connected cells is to laser scribe the module 10 to divide the device into a series of cells connected by interconnects. Also, electrical wires can be connected to positive and negative terminals of the PV module 10 to provide lead wires to harness electrical current produced by the PV module 10.

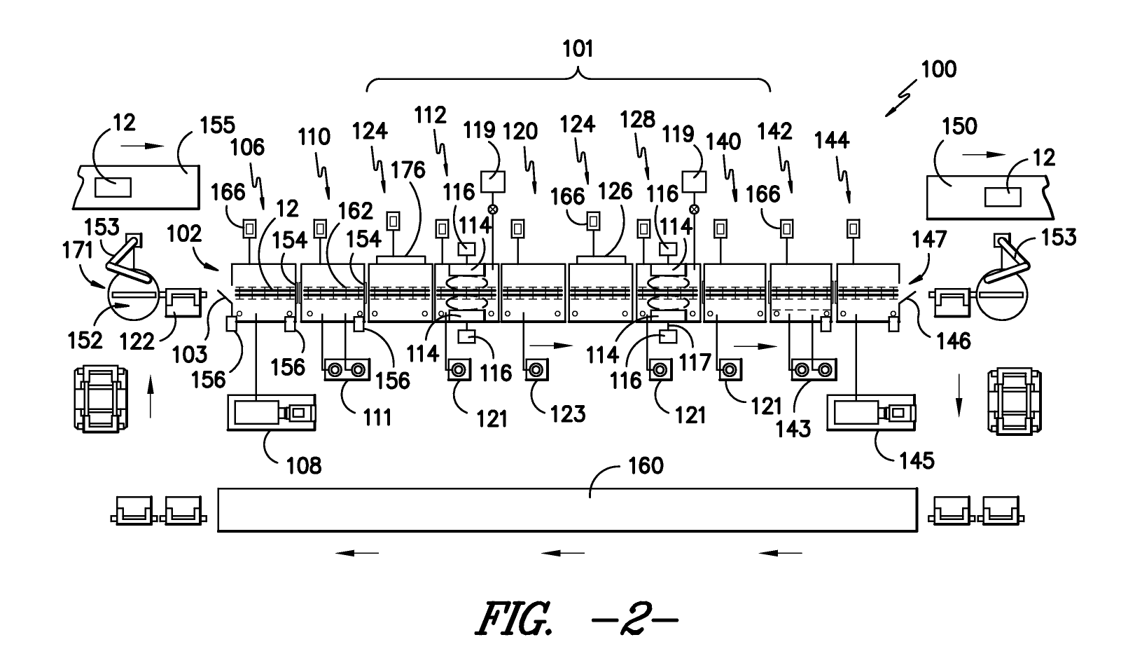

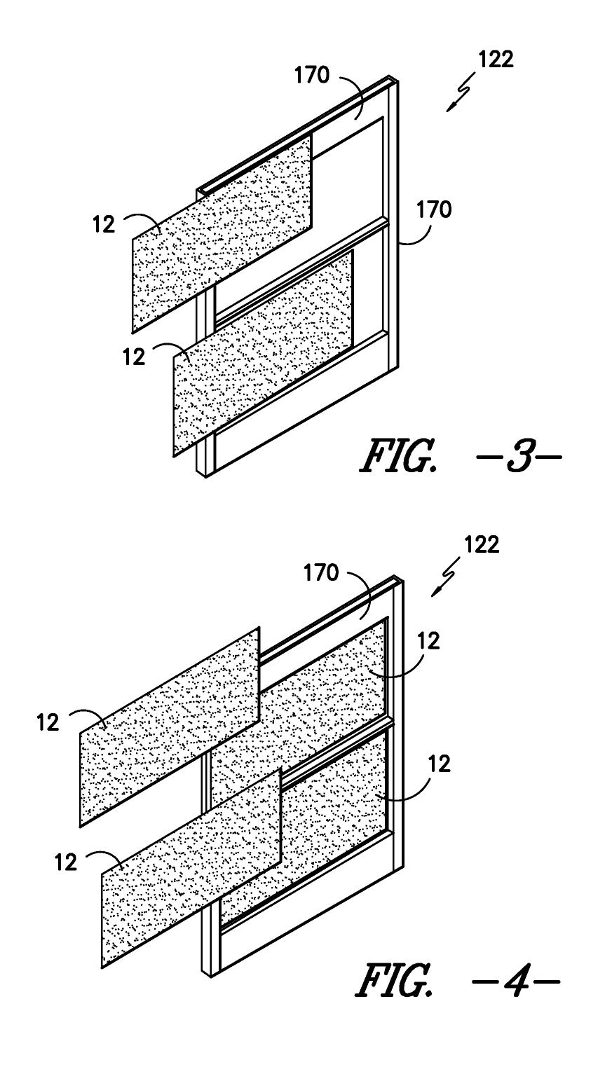

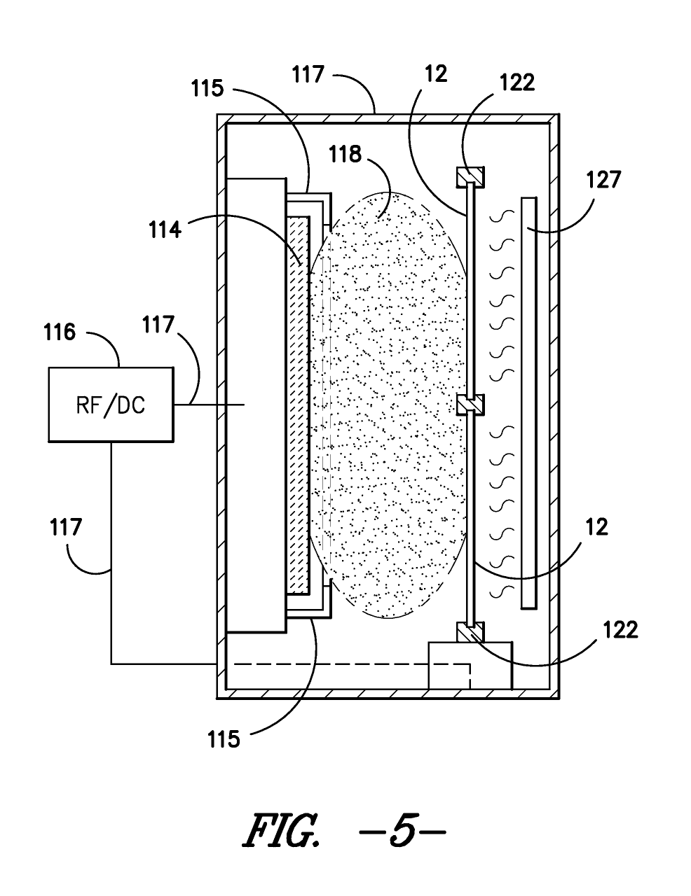

FIG. 2 represents an exemplary integrated deposition system 100 in accordance with aspects of the invention for deposition of multiple thin film layers on PV module substrates 12 (FIGS. 3 and 4) that are conveyed through the system 100. It should be noted that the system 100 is not limited by any particular type of thin film or thin film deposition process, as described in greater detail herein. In one embodiment, the system 100 can be utilized to sequentially deposit, via sputtering deposition, the RTB layer 16 over the TCO layer 14 and then the CdS layer 18 over the RTB layer 16.

The integrated deposition system 100 shown in FIG. 2 includes a load vacuum chamber 106, a first sputtering chamber 112, a vacuum buffer chamber 120, and a second sputtering chamber 128. Each of the chambers is integrally interconnected together such that the substrates 12 passing through the system 100 are substantially protected from the outside environment within the integrated vacuum 101. In other words, the chambers 112, 120, and 128 of the system 100 are directly integrated together such that a substrate 12 exiting one chamber immediately enters the adjacent section directly, without exposure to the room atmosphere. Thus, the substrates 12 can be protected from outside contaminants being introduced into the thin films, resulting in more uniform and efficient devices. Of course, other intermediary chambers may be included within the system 100, as long as the system remains integrally interconnected to the other chambers of the system 100.

Through the integration of these deposition chambers into a single system, the energy consumption required for the deposition of the sputtered layers (e.g., a RTB layer and a CdS layer) can be reduced, when compared from separated deposition systems, during the manufacturing of a cadmium telluride thin film device. For instance, once the load vacuum is drawn in the load vacuum chamber 106, no need for an additional load vacuum chambers exists, since the system pressure can remain below atmospheric pressure (i.e., about 760 Torr) through the first sputtering chamber 112, the vacuum buffer chamber 120, and the second sputtering chamber 128. For example, in certain embodiments, the system pressure can remain below 250 Ton, such as about 3 mTorr to about 100 Ton. In one particular embodiment, the system pressure can remain below the initial load vacuum pressure (e.g., less than about 250 mTorr). For example, in one embodiment, the system pressure can be substantially constant through the first sputtering chamber 112, the vacuum buffer chamber 120, and the second sputtering chamber 128 (and any chambers positioned therebetween).

The illustrated system 100 includes a loading system 171 wherein substrates 12 are loaded onto carriers 122 and then conveyed into the load vacuum chamber 106. The substrates 12 may be loaded into the carriers 122 in a load station 152 by automated machinery 153 from the supply conveyor 155. For example, robots or other automated machinery may be used for this process. In an alternative embodiment, the substrates 12 may be manually loaded onto carriers 122.

As shown in FIG. 2, the individual substrates 12 first enter the load vacuum chamber 106 through the entry slot 102. The first entry slot 102 defines a flap 103 that can close to separate the internal atmosphere within the load vacuum chamber 106 from the outside environment. The load vacuum chamber 106 is connected to a load vacuum pump 108 configured to draw a load pressure within the load vacuum chamber 106. Specifically, the load vacuum pump 108 can reduce the pressure within the load vacuum chamber 106 to an initial load pressure of about 1 mTorr to about 250 mTorr.

The substrates 12 can then pass from the load vacuum chamber 106 into the fine vacuum chamber 110 connected to the fine vacuum pump 111 that can reduce the pressure to an increased vacuum. For instance, the fine vacuum chamber(s) 110 can reduce the pressure to about 1×10⁻⁷ Torr to about 1×10⁻⁴ Ton, and then be backfilled with an inert gas (e.g., argon) in a subsequent chamber within the system 100 (e.g., within the sputtering deposition chamber 112) to a deposition pressure (e.g., about 10 mTorr to about 100 mTorr).

In the embodiment shown, the individual carriers 122 associated with the adjacently disposed vertical substrates 12 are controlled so as to convey the substrates 12 through the system at a controlled, constant linear speed to ensure an even deposition of the thin film onto the surface of the substrates 12. On the other hand, the carriers 122 and substrates 12 are introduced in a step-wise manner into and out of system 100. In this regard, the load vacuum chamber 106 and the fine vacuum chamber 110 are configured with vacuum lock valves 154 with associated controllers 156. Additional, non-vacuum modules at the entry for loading the carriers 122 into the system 100, and buffering the carriers 122 relative to the outside atmosphere may also be included.

For example, referring to FIG. 2, the system 100 includes a plurality of adjacently disposed vertical processing modules. A first one of these modules (i.e., the load vacuum chamber 106) defines an entry vacuum valve 103, which may be, for example, a gate-type slit valve or rotary-flapper valve that is actuated by an associated actuator 156. The initial valve 103 is open and a carrier 122 is conveyed into the load vacuum chamber 106 from the load module 152. The entry valve 103 is then closed. At this point, the “rough” vacuum pump 108 pumps from atmosphere to an initial “rough” vacuum in the millitorr range. The rough vacuum pump 162 may be, for example, a claw-type mechanical pump with a roots-type blower. Upon pumping to a defined crossover pressure, the valve 154 between the load vacuum chamber 106 and an adjacent fine vacuum chamber 110 is opened and the carrier 122 is transferred into the fine vacuum chamber 110. The valve 154 between the chambers 106 and 110 is then closed, the load vacuum chamber 106 is vented, and the initial valve 103 is opened for receipt of the next carrier 122 into the module. A “high” or “fine” vacuum pump 111 draws an increased vacuum in the fine vacuum chamber 110, and the fine vacuum chamber 110 may be backfilled with process gas to match the conditions in the downstream processing chambers. The fine vacuum pump 111 may be, for example, a combination of cryopumps or turbo molecular pumps configured for pumping down the module to about less than or equal to 9×10⁻⁵ torr. Finally, the valve 154 between the fine vacuum chamber 110 and the integrated chamber 101 is opened and the carrier 122 is transferred into the first module of the integrated chamber 101 (e.g., an optional heating chamber 124 or the first sputtering chamber 119).

The substrates 12 are then transferred from the load vacuum chamber 106 and fine vacuum chamber 110 to the first sputtering deposition chamber 112 and second sputtering chamber 128. Between the first sputtering deposition chamber 112 and second sputtering chamber 128 is a buffer vacuum chamber 120 connected to the buffer vacuum pump 123 configured to remove any residual particles from the atmosphere and/or substrates 12 passing therethrough. As such, the buffer vacuum chamber 120 can inhibit cross-contamination between the first sputtering deposition chamber 112 and the second sputtering chamber 128. In one embodiment, a backfill gas port configured to provide an inert gas to the vapor deposition temperature can be included within the vacuum buffer pump 122. In one particular embodiment, the buffer vacuum chamber 120 can include slit valves on its entry slit and/or its exit slit to further inhibit cross-contamination between the first sputtering deposition chamber 112 and second sputtering chamber 128.

Sputtering deposition generally involves ejecting material from a target, which is the material source, and depositing the ejected material onto the substrate to form the film. DC sputtering generally involves applying a direct current to a metal target (i.e., the cathode) positioned near the substrate (i.e., the anode) within a sputtering chamber to form a direct-current discharge. The sputtering chamber can have a reactive atmosphere (e.g., including sulfur in addition to oxygen, nitrogen, etc.) that forms a plasma field between the metal target and the substrate. Other inert gases (e.g., argon, etc.) may also be present. The pressure of the reactive atmosphere can be between about 1 mTorr and about 20 mTorr for magnetron sputtering. The pressure can be even higher for diode sputtering (e.g., from about 25 mTorr to about 100 mTorr). When metal atoms are released from the target upon application of the voltage, the metal atoms deposit onto the surface of the substrate. For example, when the atmosphere contains oxygen, the metal atoms released from the metal target can form a metallic oxide layer on the substrate. The current applied to the source material can vary depending on the size of the source material, size of the sputtering chamber, amount of surface area of substrate, and other variables. In some embodiments, the current applied can be from about 2 amps to about 20 amps. Conversely, RF sputtering involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere) which may or may not contain reactive species (e.g., oxygen, nitrogen, etc.) having a pressure between about 1 mTorr and about 20 mTorr for magnetron sputtering. Again, the pressure can be even higher for diode sputtering (e.g., from about 25 mTorr to about 100 mTorr).

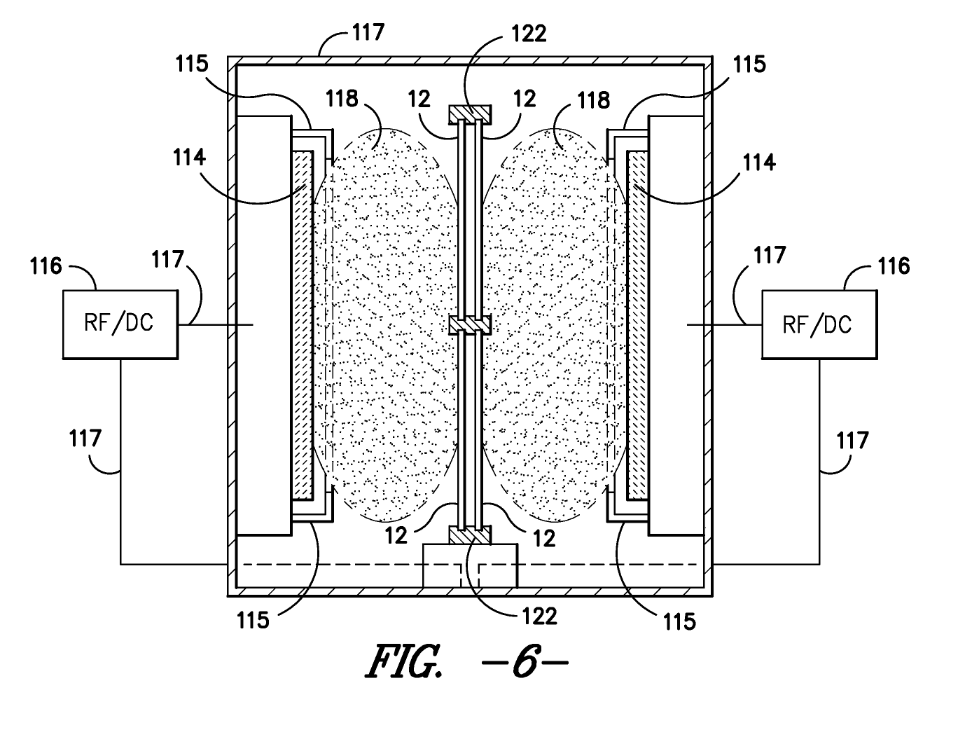

As shown, the each of the first sputtering deposition chamber 112 and the second sputtering chamber 128 generally includes a target 114 connected to a power source 116 (e.g., a DC or RF power source) via wires 117. The power source 116 is configured to control and supply power (e.g., DC, RF, or pulsed DC power) to the sputtering deposition chamber 112. As shown in FIGS. 5 and 6, the power source 116 applies a voltage to the target 114 (acting as the cathode) to create a voltage potential between the target 114 and an anode formed by the shields 115 and the chamber walls 117, such that the substrates 12 is within the magnetic fields formed therebetween. Although only a single power source 116 is shown for each target 114, the voltage potential can be realized through the use of multiple power sources coupled together.

The substrates 12 are generally positioned within the sputtering deposition chamber 112 such that a thin film layer (e.g., a RTB layer or a CdS layer) is formed on the surface of the substrates 12 facing the target 114. A plasma field 118 is created once the sputtering atmosphere is ignited, and is sustained in response to the voltage potential between the target 114 and the chamber walls 110 acting as an anode. The voltage potential causes the plasma ions within the plasma field 118 to accelerate toward the target 114, causing atoms from the target 114 to be ejected toward the surface on the substrate 12. As such, the target 114 (also can be referred to as the cathode) acts as the source material for the formation of the thin film layer on the surface of the substrate 12 facing the target 114.

A sputtering atmosphere control system 119 can control the sputtering atmosphere within the sputtering deposition chamber 112, such as reducing to the sputtering pressure (e.g., about 10 to about 25 mTorr). Generally, the sputtering atmosphere control system 119 can provide an inert gas (e.g., argon) to the sputtering deposition chamber 112. Optionally, the sputtering atmosphere can also include oxygen, allowing oxygen particles of the plasma field 118 to react with the ejected target atoms to form a thin film layer that includes oxygen. A sputtering vacuum 121 can also be included to control the pressure in the sputtering chamber 112.

For example, the sputtering deposition chamber 112 can be utilized to form a cadmium sulfide layer on the substrate. In this embodiment, the target 114 can be a ceramic target, such as of cadmium sulfide. Additionally, in some embodiments, a plurality of targets 114 can be utilized. A plurality of targets 114 can be particularly useful to form a layer including several types of materials (e.g., co-sputtering).

Optionally, the substrates 12 can be transferred into and through a heating chamber 124 positioned prior to either of the first sputtering deposition chamber 112 and the second sputtering chamber 128, such as shown in FIG. 1. The heating chamber 124 can include a heating element 126 configured to heat the substrates 12 to a sputtering temperature prior to entering the sputtering chamber 112 and/or 128, such as about 50° C. to about 250° C., depending on the parameters of the sputtering deposition. In an alternative embodiment, the sputtering chamber 112 and/or 128 can optionally include heaters 127 configured to heat the substrates 12 within the sputtering chamber 112 and/or 128 (as shown in FIG. 5) instead of, or in addition to, the heating chamber 124.

To exit the system 100, the substrates 12 can pass through an optional exit buffer vacuum chamber 140 connected to a buffer vacuum 121. The substrates 12 can then pass through a series of exit valves 154 controlled by independent motors 156 to exit the system 100 while maintaining the vacuum within the integrated chamber 101. As such, the carriers 122 and substrates 12 can pass through the valve 154 between the exit buffer vacuum chamber 140 and into a first exit lock chamber 142 connected to a first exit lock pressure system 143. The valve 154 can then be closed, and the first exit lock chamber 142 vented to a “rough” exit pressure. Then, the valve 154 between the first exit lock chamber 142 and the second exit lock chamber 144 can be opened and the substrates 12 conveyed therethrough. The valve 154 between the first exit lock chamber 142 and the second exit lock chamber 144 can then be closed and the second exit lock chamber 144 vented to atmospheric pressure. The exit valve 146 can then be opened, and the carriers 122 removed from the system 100 through the exit slot 147. The substrates 12 can be removed from the carrier 122, and placed on the post-processing conveyor 150 for further processing via machine arm 153. The carriers 122 can then be returned to the start of the system 100 via return conveyor 160.

Carriers 122 can have one or more substrates loaded thereon are introduced into the system 100. In the embodiment shown in FIGS. 2 and 6, the carriers 122 can be configured for simultaneous deposition of substrates 12 positioned back-to-back.

Each of the chambers may include an independently driven and controlled conveyor system 162 for moving the substrate carriers 122 in a controlled manner through the respective chambers. In particular embodiments, the conveyors 162 may be roller-type conveyors, belt conveyors, and the like. The conveyors 162 for each of the respective chambers may be provided with an independent drive (not illustrated in the figure).

The various substrates 12 can be vertically oriented in that the carriers 122 to convey the substrates 12 in a vertical orientation through the system 100. Referring to FIG. 4, an exemplary carrier 122 is illustrated as a frame-type of structure made from frame members 170. The frame members 170 define receipt positions for substrates 12 such that the substrates 12 are horizontally or vertically received (relative to their longitudinal axis) within the carrier 122. It should be appreciated that the carrier 122 may be defined by any manner of frame structure or members so as to carry one or more of the substrates 12 in a vertical orientation through the processing sides. In the embodiment of FIG. 4, the carrier 122 is configured for receipt of two substrates 12 in a horizontal position. It should be readily appreciated that the multiple substrates 12 could also be disposed such that the longitudinal axis of the respective substrates is in a vertical position. Any orientation of the substrates 12 within the carrier 122 is contemplated within the scope and spirit of the invention. The frame members 124 may define an open-type of frame wherein the substrates 12 are essentially received within a “window opening” defined by the carrier 122. In an alternative embodiment, the carrier 122 may define a back panel against which the substrates 12 are disposed.

The embodiment of the carrier 122 illustrated in FIG. 5 is configured for receipt of four substrates 112, wherein pairs of the substrates 12 are in a back-to-back relationship. For example, a pair of the substrates 12 is disposed in the upper frame portion of the carrier 112, and a second pair of the substrates 12 is disposed in the lower frame portion of the carrier 112. The configuration of FIG. 5 may be used when four or more of the substrates 12 are simultaneously processed in the system 100, as described in greater detail below with respect to the deposition apparatus illustrated in FIG. 7.

Referring again to FIG. 2, the system 100 may be particularly configured with at least two vertical sputtering chambers for subsequent deposition of a zinc-tin oxide (ZTO) layer on the substrates conveyed therethrough and then a cadmium sulfide (CDS) layer on the ZTO layer. Operation of vacuum sputtering chambers is well known to those skilled in the art and need not be described in detail herein.

FIG. 5 shows a general schematic cross-sectional view of an exemplary vertical deposition chamber 119. A power source 116 is configured to control and supply DC or RF power to the chamber 119. In the case of a DC chamber 119, the power source 116 applies a voltage to the cathode 114 to create a voltage potential between the cathode 114 and an anode. In the illustrated embodiment, the anode is defined by the shield 115 and the chamber wall 117. The glass substrates 12 are held by the carrier 122 so as to be generally opposite from the cathode 114 (which is also the target source material). A plasma field 118 is created once the sputtering atmosphere is ignited and is sustained in response to the voltage potential between the cathode 114 and the anode. The voltage potential causes the plasma ions within the plasma field 118 to accelerate towards the cathode 114, causing atoms from the cathode 114 to be ejected towards the surface of the substrates 12. As such, the cathode 114 is the “target” and is defined by the source material for formation of the particular type of thin film desired on the surface of the substrates 12. For example, the cathode 114 can be a metal alloy target, such as elemental tin, elemental zinc, or mixtures of different metal alloys. Oxygen in the chamber 166 reacts with the ejected target atoms to form an oxide layer on the substrates 12, such as a ZTO layer.

A cadmium sulfide (CdS) thin film layer may be formed in an RF sputtering chamber 119 (FIG. 5) by applying an alternating-current (AC) or radial-frequency (RF) signal between a ceramic target source material and the substrates 12 in an essentially inert atmosphere.

Although single power sources are illustrated in FIGS. 5 and 6, it is generally understood that multiple power sources may be coupled together with a respective target source for generating the desired sputtering conditions within the chamber 166.

FIG. 5 illustrates a heater element 127 within the chamber 119. Any manner or configuration of heater elements may be configured within the chamber 119 to maintain a desired deposition temperature and atmosphere within the chamber.

In the embodiment of FIG. 5, the vertical deposition module 128 is configured for deposition of a thin film layer on the side of the substrates 12 oriented towards the target source material 114. FIG. 6 illustrates an embodiment wherein the chamber 119 includes dual sputtering systems for applying a thin film onto the outwardly facing surfaces of the back-to-back substrates 12 secured in the carriers 122, such as the carrier 122 configuration illustrated and described above with respect to FIG. 4. Thus, with the vertical deposition module 119 illustrated in FIG. 6, four substrates are simultaneously processed for deposition of a particular thin film layer thereon.

The system 100 in FIG. 2 is defined by a plurality of interconnected chambers, as discussed above, with each of the chambers serving a particular function. The respective conveyors configured with the individual modules are also appropriately controlled for various functions, as well as the valves 154 and associated actuators 156. For control purposes, each of the individual chambers may have an associated controller 166 configured therewith to control the individual functions of the respective module.

It should be readily appreciated that, although the deposition chambers 119 are described herein in particular embodiments as sputtering deposition modules, the invention is not limited to this particular deposition process. The vertical deposition chambers 119 may be configured as any other suitable type of processing chamber, such as a chemical vapor deposition chamber, thermal evaporation chamber, physical vapor deposition chamber, and so forth. In the particular embodiments described herein, the first deposition chamber may be configured for deposition of a ZTO layer and the second deposition chamber may be configured for deposition of a CdS layer on the ZTO layer. Each chamber 119 may be configured with four DC water-cooled magnetrons. As mentioned above, each chamber 119 may also include one or more vacuum pumps mounted on the back chambers between each cathode pair.

The present invention also encompasses various process embodiments for deposition of multiple thin film layers on a photovoltaic (PV) module substrate. The processes may be practiced with the various system embodiments described above or by any other configuration of suitable system components. It should thus be appreciated that the process embodiments according to the invention are not limited to the system configuration described herein.

In a particular embodiment, the process includes transporting the substrates into a load vacuum chamber connected to a load vacuum pump to draw a vacuum in the load vacuum chamber using the load vacuum pump until an initial load pressure is reached in the load vacuum chamber. Optionally, the substrate can be transported into and through a buffer vacuum chamber and/or a heating chamber as discussed above with respect to FIG. 2. The substrate can then be transferred from the load vacuum chamber into a first sputtering deposition chamber including a first target source material (e.g., including zinc and tin or a zinc/tin oxide), where the first target source material can be sputtered to form a first thin film layer (e.g., a resistive transparent buffer layer) on the substrate. The substrate can then transferred from the first sputtering deposition chamber into a second sputtering deposition chamber including a second target source material (e.g., cadmium sulfide), where the second target source material can be sputtered to form a second thin film layer (e.g., a CdS layer) on the first thin film layer. The substrate can be transported through the load vacuum chamber, the first sputtering deposition chamber, and the second sputtering deposition chamber at a system pressure that is less than about 760 Torr. Optionally, the substrates can be transported into and through a buffer vacuum chamber as discussed above with respect to FIG. 2.

The process may include moving the carriers and attached substrates into and out of vacuum chambers in a step-wise manner, for example through a series of vacuum locks, yet conveying the carriers and attached substrates through the vacuum chambers at a continuous linear speed during the deposition process.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. An apparatus for sequential sputtering deposition of a target source material as a thin film on a photovoltaic module substrate, said apparatus comprising:
a load vacuum chamber connected to a load vacuum pump configured to reduce the pressure within the load vacuum chamber to an initial load pressure;
a first sputtering deposition chamber comprising a first target;
a second sputtering deposition chamber comprising a second target; and,
a conveyor system operably disposed within the apparatus and configured for transporting substrates in a serial arrangement into and through load vacuum chamber, into and through the first sputtering deposition chamber, and into and through the second sputtering deposition chamber at a controlled speed, wherein the first sputtering deposition chamber and the second sputtering deposition chamber are integrally connected such that the substrates being transported through the apparatus are kept at a system pressure that is less than about 760 Torr.

2. The apparatus as in claim 1, further comprising:
a heating chamber positioned between the load vacuum chamber and the first sputtering deposition chamber, wherein the heating chamber is configured to heat the substrates to a first sputtering deposition temperature prior to entering the first sputtering deposition chamber.

3. The apparatus as in claim 1, further comprising:
a plurality of heating chambers positioned between the load vacuum chamber and the first sputtering deposition chamber, wherein the plurality of heating chambers are configured to heat the substrates to a sputtering temperature prior to entering the first sputtering deposition chamber.

4. The apparatus as in claim 1, further comprising:
a vacuum buffer chamber positioned between the first sputtering deposition chamber and the second sputtering deposition chamber, wherein the vacuum buffer chamber is connected to a buffer vacuum pump configured to reduce the pressure within the vacuum buffer chamber to a buffer pressure;

5. The apparatus as in claim 1, further comprising:
a fine vacuum chamber connected to a fine vacuum pump, wherein the fine vacuum chamber is positioned between the load vacuum chamber and the first sputtering deposition chamber to refine the pressure within the first sputtering deposition chamber during deposition.

6. The apparatus as in claim 1, wherein the first target comprises zinc and tin.

7. The apparatus as in claim 1, wherein the second target comprises cadmium sulfide.

8. A process of manufacturing a thin film cadmium telluride thin film photovoltaic device, the process comprising:
transporting a substrate into a load vacuum chamber connected to a load vacuum pump;
drawing a vacuum in the load vacuum chamber using the load vacuum pump until an initial load pressure is reached in the load vacuum chamber;
transporting the substrate from the load vacuum chamber into a first sputtering deposition chamber, wherein the first sputtering deposition chamber comprises a first target source material;
sputtering the first target source material to form a first thin film layer on the substrate;
transporting the substrate from the first sputtering deposition chamber into a second sputtering deposition chamber, wherein the second sputtering deposition chamber comprises a second target source material; and,
sputtering the second target source material to form a second thin film layer on the first thin film layer,
wherein the substrate is transported through the first sputtering deposition chamber and the second sputtering deposition chamber while remaining under a system pressure that is less than about 760 Torr.

9. The process as in claim 8, wherein the first target source material comprises is sputtered to form a resistive transparent buffer layer on the substrate, and wherein the second target source material is sputtered to form a cadmium sulfide layer on the resistive transparent buffer layer.

10. The process as in claim 9, wherein the first target source material comprises zinc and tin.

11. The process as in claim 9, wherein the second target source material comprises cadmium sulfide.

12. The process as in claim 8, further comprising:
transporting the substrate from the load vacuum chamber into a heating chamber positioned between the load vacuum chamber and the first sputtering deposition chamber; and,
heating the substrate within the heating chamber to a first sputtering deposition temperature prior to entering the first sputtering deposition chamber.

13. The process as in claim 8, further comprising:
transporting the substrate from the load vacuum chamber into and through a series of heating chambers sequentially positioned between the load vacuum chamber and the first sputtering deposition chamber; and,
heating the substrate within plurality of the heating chambers to a sputtering deposition temperature prior to entering the first sputtering deposition chamber.

14. The process as in claim 8, further comprising:
transporting the substrate into and through a vacuum buffer chamber positioned between the first sputtering deposition chamber and the second sputtering deposition chamber, wherein the vacuum buffer chamber is connected to a buffer vacuum pump configured to reduce the pressure within the vacuum buffer chamber to a buffer pressure.

15. The process as in claim 8, wherein the initial load pressure is about 1 mTorr to about 100 mTorr.

16. The process as in claim 8, further comprising:
transporting the substrate from the load vacuum chamber into and through a fine vacuum chamber, wherein the fine vacuum chamber is connected to a fine vacuum pump to draw a deposition pressure.

17. The process as in claim 16, wherein the deposition pressure is about 1 mTorr to about 10 Torr.

18. The process as in claim 8, further comprising:
transporting the substrate from the second sputtering deposition chamber into and through an exit vacuum chamber after the second sputtering deposition chamber.
